(19) United States
(12) Patent Application Publication
(10) Pub. No.: US 2021/0078204 A1
(43) Pub. Date: Mar. 18, 2021

(54) CUTTING BLADE AND MANUFACTURING METHOD OF CUTTING BLADE

(71) Applicant: DISCO CORPORATION, Tokyo (JP)

(72) Inventors: Takashi FUKAZAWA, Tokyo (JP); Shigeru HATTORI, Tokyo (JP)

(21) Appl. No.: 17/016,713

(22) Filed: Sep. 10, 2020

(30) Foreign Application Priority Data
Sep. 12, 2019 (JP) 2019-166094

(51) Int. Cl. B28D 5/02; H01L 21/3105; B26D 1/00

(52) U.S. Cl. CPC B28D 5/022; B26D 2001/002; B26D 1/0006; H01L 21/3105

(57) ABSTRACT

A cutting blade, which can cut an insulating film while suppressing exfoliation of the insulating film such as a Low-k film that is likely to be exfoliated upon cutting, is demanded. A cutting blade, that can meet this demand, has a binder and abrasive particles, in which the abrasive particles are fixed by the binder at least part of which is glassy carbon.

### BACKGROUND OF THE INVENTION

### Field of the Invention

The present invention relates to a cutting blade in which abrasive particles are fixed with a binder, a manufacturing method of the cutting blade, and a cutting method for a wafer by which an insulating film provided on one face side of a wafer is cut by the cutting blade.

### Description of the Related Art

A method of dividing a wafer, which has regions partitioned by a plurality of scheduled division lines set on a front face side thereof and has such a device as an integrated circuit (IC) or a large scale integration (LSI) formed in each of the regions thereof, along the scheduled division lines is known. On the front face side of a wafer, a multilayer wiring layer is formed in which an insulating film and a metal layer are stacked alternately. In order to improve the processing capacity of circuits such as ICs or LSIs, the insulating film is sometimes formed of a low dielectric constant insulator material (namely, a Low-k material). As the Low-k material, inorganic materials such as SiO₂, SiOF, and SiOB and organic materials such as polyimide materials and parylene materials are used.

In the case where an insulating film made of a Low-k material (namely, a Low-k film) is stacked in a multilayer wiring layer, there is a problem that, if the multilayer wiring layer is cut along a scheduled division line by a cutting blade, then a crack or a break occurs with the Low-k film and gives rise to exfoliation of the Low-k film from the wafer. Therefore, generally a laser beam is irradiated upon the front face side of the wafer along a scheduled division line to form a laser processed groove from which the multilayer wiring layer is partly removed (for example, refer to Japanese Patent Laid-Open No. 2004-188475 and Japanese Patent Laid-Open No. 2005-64230). Then, after such laser processed grooves are formed, a cutting blade or a laser beam is used to cut a bottom of the laser processed grooves to sever the wafer to manufacture a plurality of device chips.

### SUMMARY OF THE INVENTION

However, since a laser processing apparatus is expensive, if a multilayer wiring layer can be removed along scheduled division lines without using a laser beam, then the cost required for wafer division can be reduced. Therefore, a cutting blade is demanded which can cut an insulating film such as a Low-k film that is likely to be exfoliated upon cutting while the exfoliation of the insulating film is suppressed. The present invention has been made in view of such a problem as just described, and it is an object of the present invention to provide a cutting blade that can cut an insulating film, which is likely to be exfoliated upon cutting, while exfoliation of the insulating film is suppressed.

In accordance with an aspect of the present invention, there is provided a cutting blade having a binder and abrasive particles, in which the abrasive particles are fixed by the binder at least part of which is glassy carbon.

Preferably, the abrasive particles of the cutting blade have an average particle size equal to or smaller than 12 μm.

In accordance with another aspect of the present invention, there is provided a manufacturing method of a cutting blade in which abrasive particles are fixed by a binder, including a molding step of forming a molded body of a predetermined shape from mixture including a thermosetting resin and the abrasive particles, a baking step of baking the molded body at a temperature equal to or higher than 100° C. and equal to or lower than 300° C. to form a baked body, and a heat treatment step of heat treating the baked body at a temperature equal to or higher than 500° C. and equal to or lower than 1500° C. under an inert gas atmosphere or a vacuum atmosphere. In the heat treatment step, at least part of the thermosetting resin is the binder of glassy carbon.

In accordance with a further aspect of the present invention, there is provided a cutting method of a wafer for cutting an insulating film provided on a front face side of a wafer on which a device is formed in each of a plurality of regions partitioned by scheduled division lines set in a grating pattern, the cutting method including a holding step of sucking and holding a rear face side positioned on an opposite side to the front face of the wafer by a chuck table to hold the wafer in a state in which the front face side is exposed, and a cutting step of cutting the insulating film positioned on the front face side along the scheduled division lines using a cutting blade in which abrasive particles are fixed by a binder at least part of which is glassy carbon.

Preferably, in the cutting step, the insulating film is cut using the cutting blade in which the abrasive particles have an average particle size equal to or smaller than 12 μm.

In the cutting blade according to the mode of the present invention, the abrasive particles are fixed by the binder at least part of which is glassy carbon. Since a hardness of the cutting blade that includes the glassy carbon in the binder is high in comparison with a hardness of a general resin bond blade, the blade thickness can be reduced in comparison with the general resin bond blade. Therefore, a kerf width that is small in comparison with that of the general resin bond blade can be implemented. Further, since the cutting blade that includes the glassy carbon in the binder thereof has a nature that it is brittle although it is comparatively hard, the self-sharpening effect is likely to occur in comparison with an electroformed bond blade or a metal bond blade. Therefore, since, in comparison with an alternative case in which an electroformed bond blade or a metal bond blade is used for cutting, the cutting blade is less likely to give a shock to the insulating film that is likely to exfoliate, a break or a crack is less likely to occur with the insulating material. Therefore, exfoliation of the insulating film that is likely to exfoliate upon cutting can be suppressed.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a cutting blade;

FIG. 2 is a flow chart illustrating a manufacturing method of the cutting blade;

FIG. 3 is a schematic view illustrating a compounding step;

FIG. 4A is an exploded perspective view of a metal mold used in a molding step;

FIG. 4B is a perspective view depicting the metal mold to which mixture is supplied;

FIG. 5A is a sectional view depicting the mixture supplied to the metal mold;

FIG. 5B is a sectional view depicting a manner in which the mixture supplied to the metal mold is leveled;

FIG. 5C is a sectional view depicting a manner in which a through-hole of an upper punch is fitted with a middle punch;

FIG. 5D is a sectional view depicting a manner in which the mixture is molded to form a molded body;

FIG. 6A is a perspective view of a wafer unit;

FIG. 6B is a sectional view of a wafer and so forth;

FIG. 7A is a perspective view of the wafer unit and so forth in the cutting step;

FIG. 7B is a sectional view of the wafer and so forth in the cutting step; and

FIG. 8 is a flow chart illustrating a cutting method.

### DETAILED DESCRIPTION OF THE PREFERRED EMBODIMENT

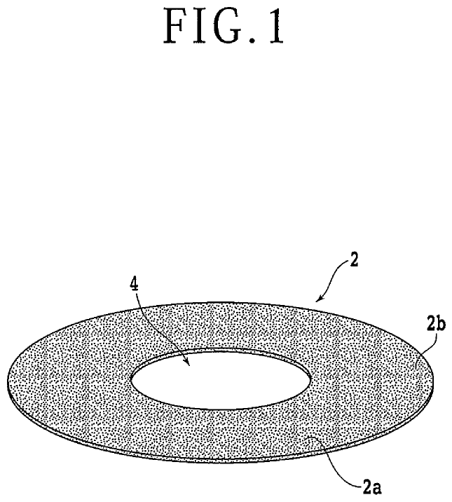

An embodiment according to a mode of the present invention is described with reference the accompanying drawings. FIG. 1 is a perspective view of a cutting blade 2. The cutting blade 2 is a washer type (also called hubless type) blade the entirety of which is configured from abrasive particles 2a and a binder 2b (bond). Although the abrasive particles 2a are formed of diamond, the material of which the abrasive particles 2a is formed is not limited to diamond. The abrasive particles 2a may be formed of cBN (cubit boron nitride), white alundum (WA), green carbon (GC) or the like.

The particle size of the abrasive particles 2a is very small, and the average particle size is 12 μm or less. The average particle size is specified, for example, in the case where the size of one particle is represented by a predetermined particle size (namely, length), on the basis of a frequency distribution of a particle group represented using the particle size. As the method of expressing a particle size, known methods such as a geometric diameter, an equivalent diameter and so forth are available. As the geometric diameter, a Feret diameter, a maximum diameter in a fixed direction (namely, a Krummbein diameter), a Martin diameter, a sieve diameter and so forth are available. As the equivalent diameter, an equivalent diameter of a projection area (namely, a Heywood diameter), an equivalent surface diameter, an equivalent volume diameter, a Stokes diameter, a light scattering diameter and so forth are available. Thus, in the case where a frequency distribution in a particle group is produced with the particle size (μm) on the abscissa and with the frequency on the axis of ordinate, for example, the average diameter of a weight standard distribution or a volume standard distribution is an average particle size.

It is to be noted that the particle size of the abrasive particle 2a may be specified not using the average particle size but using a grain size (#) prescribed by JIS R6001-2 of the JIS (Japanese Industrial Standards) standard. For example, a grain size (#) specified by a grain size distribution of fine powder for precision polishing measured by a sedimentation test method or an electric resistance test method is used. In particular, as the abrasive particle 2a, fine powder having a grain size of #1000 or more (namely, #1000, #1200, #1500, #2000, #2500, #3000 and so forth) is used. It is to be noted that, as the numeral indicated to the right of # increases in value, the particle size D₅₀ (namely, median diameter) when the cumulative frequency is 50% decreases.

In the case of #1000, the particle size D₅₀ measured by the sedimentation test method is in the range of 14.5 μm to 16.4 μm, and the particle size D₅₀ measured by the electric resistance test method is in the range of 10.5 μm to 12.5 μm. Meanwhile, the particle size D₅₀ of #1200 or more is equal to 14.0 μm or less by the sedimentation test method and is 10.3 μm or less by the electric resistance test method. A plurality of abrasive particles 2a are fixed to each other by the binder 2b. As the raw material for the binder 2b, a thermosetting resin such as a phenol resin, an epoxy resin, a polyimide resin, or a melamine resin is used. After thermosetting resin and the abrasive particles 2a are compounded, they are baked and heat treated to form the binder 2b. The binder 2b after the heat treatment is partly or entirely formed of glassy carbon (glass-like carbon).

The cutting blade 2 is a ring-shaped blade having a through-hole 4 substantially at the center of one face thereof. For example, a diameter of the through-hole 4 is 35 mm to 45 mm, and an outer diameter of the cutting blade 2 is 50 mm to 90 mm. Further, a thickness of an inner circumferential portion of the cutting blade 2 (namely, a length from one face of the ring to the other face positioned on the opposite side to the one face) is, for example, 0.1 mm to 0.3 mm. It is to be noted that a thickness of an outer circumferential portion of the cutting blade 2 is smaller than the thickness of the inner circumferential portion. For example, the outer circumferential portion of the cutting blade 2 has a thickness of 20 μm to 30 μm. In order to make the outer circumferential portion of the cutting blade 2 thinner than the inner circumferential portion, for example, a dresser board is used. The dresser board includes a linear groove having a width of 20 μm to 30 μm and a sufficiently great length in comparison with the width.

In the case where the dresser board is used to modify a shape of the outer peripheral portion of the cutting blade 2, while the cutting blade 2 is rotated in its circumferential direction in a state in which the center of the width of the groove is aligned with the center of the cutting blade 2 in the thicknesswise direction, the cutting blade 2 is cut into the groove of the dresser board. As a result, the outer circumferential portion of the cutting blade 2 is thinned substantially uniformly on the one face side and the other face side thereof. In the sectional shape in the case where the cutting blade 2 is taken so as to pass the center of the ring of the cutting blade 2, the outer circumferential portion of the cutting blade 2 has a projected shape.

A width of a top portion of the projected shape (namely, the thickness of the outer circumferential portion) has a length according to the width of the groove (in the present example, 20 μm to 30 μm). The blade thickness of the outer circumferential portion of 20 μm to 30 μm is a thickness of, for example, 1/10 or more to ⅕ or less in comparison with a general resin bond blade formed by baking resin or the like as a binder. In the cutting blade 2 of the present embodiment, since glassy carbon is used for at least part of the binder 2b, the hardness of the cutting blade 2 is high in comparison with a general resin bond board. Therefore, since the blade thickness can be made smaller than that of a general resin bond blade, a small kerf width in comparison with a general resin board blade can be implemented.

In addition, if glassy carbon is used for at least part of the binder 2b, then the binder 2b becomes brittle in comparison with an electroformed bond blade or a metal bond blade. Therefore, the self-sharpening effect is likely to occur in the cutting blade 2. Accordingly, in comparison with an alternative case in which an electroformed bond blade or a metal bond blade is used for cutting, the cutting blade 2 becomes less likely to give a shock to an insulating film such as a Low-k film that is likely to exfoliate upon cutting. Therefore, since the insulating film becomes less likely to suffer from a break or a crack, exfoliation of the insulating film can be suppressed.

It is to be noted that, even if at least part of the binder 2b is formed of glassy carbon, in the case where the abrasive particle 2a is greater than the blade thickness of the cutting blade 2, the influence of the abrasive particle 2a upon a workpiece becomes dominant in comparison with the influence of the binder 2b upon a workpiece. Therefore, the average particle size of the abrasive particles 2a is preferably made smaller than the blade thickness of the outer circumferential portion of the cutting blade 2. For example, in the case where the outer circumferential portion of the cutting blade 2 has a blade thickness of 20 μm to 30 μm, the average particle size of the abrasive particles 2a is made equal to or smaller than 12 μm. Since this can reduce the influence of the abrasive particles 2a on a workpiece, exfoliation of the insulating film that is likely to be exfoliated upon cutting can be suppressed in comparison with an alternative case in which the average particle size of the abrasive particles 2a is equal to or greater than the blade thickness of the cutting blade 2.

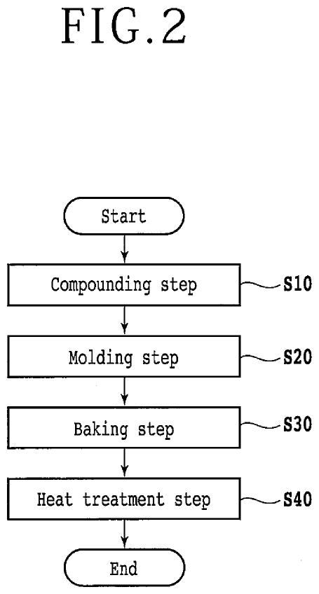

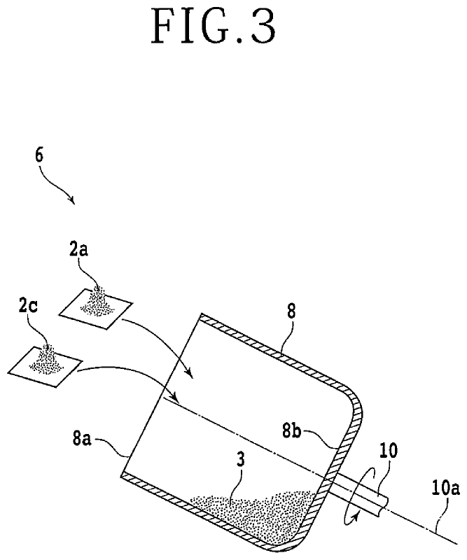

Now, a manufacturing method of the cutting blade 2 is described. FIG. 2 is a flow chart illustrating a manufacturing method of the cutting blade 2. First, abrasive particles 2a described above and a thermosetting resin 2c (for example, phenol resin) that is a raw material for the binder 2b are compounded to form mixture 3 (compounding step (S10)). FIG. 3 is a schematic view depicting the compounding step (S10). In the compounding step (S10), the plurality of abrasive particles 2a and the thermosetting resin 2c are mixed to form the mixture 3. It is to be noted that the thermosetting resin 2c is a raw material for the binder 2b. In the compounding step (S10), for example, an agitator 6 depicted in FIG. 3 is used.

The agitator 6 has a housing 8, for example, of a substantially cylindrical shape. The housing 8 has an opening 8a provided thereon. Further, on the opposite side to the opening 8a in the heightwise direction of the housing 8, a bottom wall 8b of the housing 8 exists. A shaft portion 10 is connected at one end thereof to the bottom wall 8b. To the other end of the shaft portion 10, a rotational driving source (not depicted) for rotating the shaft portion 10 around its axis is connected. If the rotational driving source is rendered operative, then the housing 8 rotates around its rotational axis 10a of the shaft portion 10.

The rotational axis 10a is inclined by a predetermined angle from the vertical direction (namely, from the direction of the gravity) as depicted in FIG. 3. Where the rotational axis 10a is inclined, when the housing 8 is rotated, agitation is performed efficiently, and therefore, the plurality of abrasive particles 2a and the thermosetting resin 2c are mixed substantially uniformly. It is to be noted that a lid member (not depicted) may be provided for the opening 8a. Further, in the inside of the housing 8, an agitation bar (not depicted) may be provided. Furthermore, a stirring blade that contacts with the material may be attached to a distal end of the agitation bar.

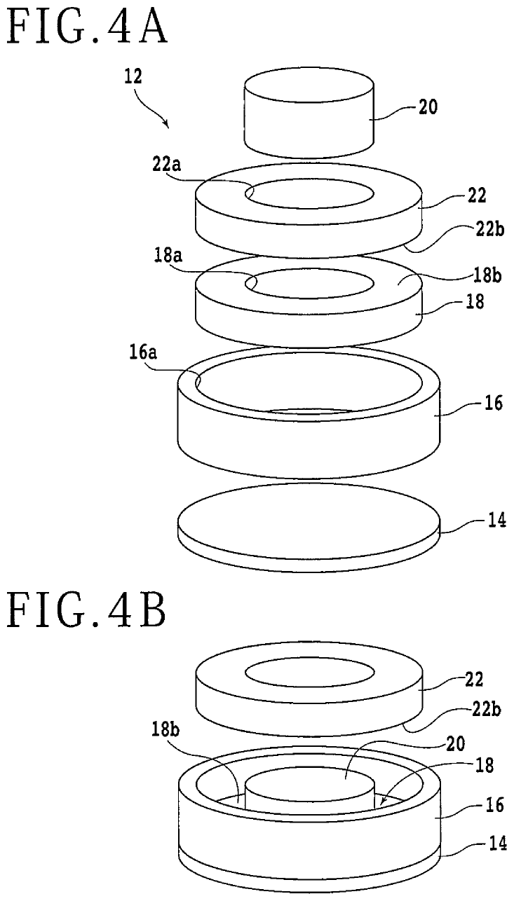

In the compounding step (S10), a plurality of abrasive particles 2a and the thermosetting resin 2c that are individually weighed to predetermined quantities are supplied through the opening 8a into the housing 8. Then, if the rotational driving source is rendered operative to rotate the housing 8, then the materials are mixed substantially uniformly to form mixture 3. After the compounding step (S10), a metal mold 12 (refer to FIGS. 4A and 4B) is used to form a molded body of a predetermined shape from the mixture 3 (molding step (S20)).

FIG. 4A is an exploded perspective view of the metal mold 12 used in the molding step (S20), and FIG. 4B is a perspective view of the metal mold 12 to which the mixture 3 is supplied. The metal mold 12 has a disk-shaped bottom plate 14. An upper face and a lower face of the bottom plate 14 have a diameter greater than the diameter of the cutting blade 2 to be manufactured. An outer cylinder 16 is provided on the bottom plate 14. The outer cylinder 16 is a cylindrical member formed with a side wall of a predetermined thickness and has a through-hole 16a. An outer diameter of the outer cylinder 16 corresponds to the outer diameter of the bottom plate 14, and the inner diameter of the outer cylinder 16 corresponds to the outer diameter of the cutting blade 2 to be manufactured. Further, a height of the outer cylinder 16 is greater than the thickness of the cutting blade 2.

A ring-shaped lower punch 18 is provided on the inner side of the outer cylinder 16 and on the bottom plate 14. An outer diameter of the lower punch 18 is substantially equal to the inner diameter of the outer cylinder 16, and a thickness of the lower punch 18 is smaller than the thickness of the outer cylinder 16. The lower punch 18 has a through-hole 18a. A cylindrical middle punch 20 is provided in the through-hole 18a of the lower punch 18. A diameter of the through-hole 18a and a diameter of the middle punch 20 are substantially equal to each other. Further, the middle punch 20 has a thickness substantially same as the thickness of the outer cylinder 16.

A ring-shaped upper punch 22 is provided on the lower punch 18. The upper punch 22 has a through-hole 22a, which is fitted in the middle punch 20. An outer diameter of the upper punch 22 is substantially equal to the inner diameter of the outer cylinder 16. Before the molding step (S20) is performed, the outer cylinder 16 is placed on the bottom plate 14, and the lower punch 18 is placed into the through-hole 16a of the outer cylinder 16. Then, the middle punch 20 is inserted into the through-hole 18a of the lower punch 18. At this time, the lower punch 18 and the middle punch 20 are supported on the bottom plate 14. In this manner, a ring-shaped space is defined and formed by the inner side face of the outer cylinder 16, an upper face 18b of the lower punch 18, and the outer circumferential side face of the middle punch 20. Thereafter, if the through-hole 22a of the upper punch 22 is fitted with the middle punch 20, then the ring-shaped space can be pressed by a lower face 22b of the upper punch 22.

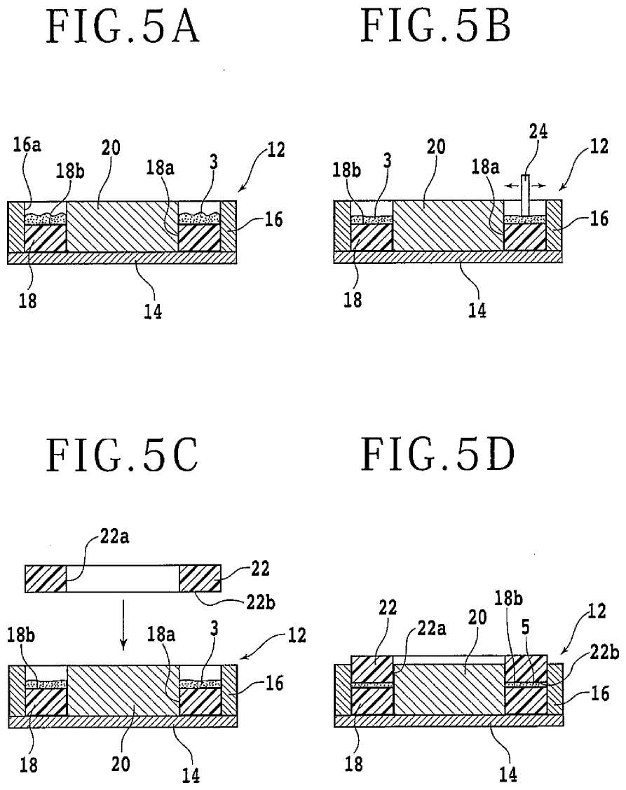

Now, the molding step (S20) in which the metal mold 12 is used is described with reference to FIGS. 5A to 5D. In the molding step (S20), mixture 3 is supplied into the ring-shaped space defined by the outer cylinder 16, the lower punch 18, and the middle punch 20. FIG. 5A is a sectional view depicting the mixture 3 supplied to the metal mold 12. Then, a leveling jig 24 is used to arrange the mixture 3 supplied to the ring-shaped space so as to become substantially flat and press the mixture 3 to the bottom of the ring-shaped space. FIG. 5B is a sectional view depicting a manner in which the mixture 3 supplied to the metal mold 12 is leveled.

Then, the through-hole 22a of the upper punch 22 is fitted with the middle punch 20, and the mixture 3 is pressed and molded by the lower face 22b of the upper punch 22. FIG. 5C is a sectional view illustrating a manner in which the through-hole 22a of the upper punch 22 is fitted with the middle punch 20, and FIG. 5D is a sectional view illustrating a manner in which the mixture 3 is molded to form a molded body 5. For example, the upper punch 22 is pressed against the lower punch 18 to press the mixture 3 with a pressure equal to or higher than 200 kgf/cm² and equal to or lower than 1000 kgf/cm², and the metal mold 12 is heated such that the mixture 3 has a temperature equal to or higher than 100° C. and equal to or lower than 200° C. In short, in the molding step (S20), the mixture 3 is molded by hot compression molding to form the ring-shaped molded body 5.

Then, the molded body 5 is baked in a baking furnace (not depicted) (baking step (S30)). The baking furnace is, for example, an electric furnace. The baking furnace bakes the molded body 5 at a temperature equal to or higher than 100° C. and equal to or lower than 300° C. (for example, at 180° C.) for 30 hours to 40 hours (for example, for 36 hours) to form a baked body in which the abrasive particles 2a are fixed by the baked thermosetting resin 2c. After the baking step (S30), the baked body is taken out from the baking furnace and is transported to a heat treatment furnace (not depicted). Then, the baked body is heat treated in the heat treatment furnace (heat treatment step (S40)). The heat treatment furnace is, for example, an electric furnace.

In the heat treatment furnace, a gas inlet port (not depicted), a suction port (not depicted) and so forth are provided, and it is possible to set the atmosphere when heat treatment is performed to an inert gas atmosphere of nitrogen, argon or the like or a vacuum atmosphere (for example, of 100 Pa or less). In the heat treatment step (S40), the baked body is placed into the heat treatment furnace. Then, the inside of the heat treatment furnace is made an enclosed space, and nitrogen gas is supplied into the furnace to place the inside of the furnace into a nitrogen atmosphere (inert gas atmosphere).

Then, the heat treatment furnace is heated, and the baked body is heat treated at a temperature equal to or higher than 500° C. and equal to or lower than 1500° C. (for example, at 800° C.) for 30 minutes to two hours (for example, for one hour) under the nitrogen atmosphere. It is to be noted that a vacuum atmosphere may be used place of the nitrogen atmosphere such that the baked body is heat treated at a temperature equal to or higher than 500° C. and equal to or lower than 1500° C. for 30 minutes to two hours. In the heat treatment step (S40), the thermosetting resin 2c partly or entirely changes into glassy carbon. The cutting blade 2 described hereinabove is manufactured thereby. It is to be noted that, after the heat treatment step (S40), truing, dressing and so forth are performed for the cutting blade 2 to shape the cutting blade 2 into a desired shape. Incidentally, although it is described in the description of the manufacturing method that the baking furnace and the heat treatment furnace are different furnaces, they may otherwise be a same furnace. For example, an electric furnace whose inside can be placed into any of the atmosphere and an inert gas atmosphere may be used such that the inside of the furnace is placed into the atmosphere to perform the baking step (S30) and then the inside of the furnace is placed into an inert gas atmosphere to perform the heat treatment step (S40).

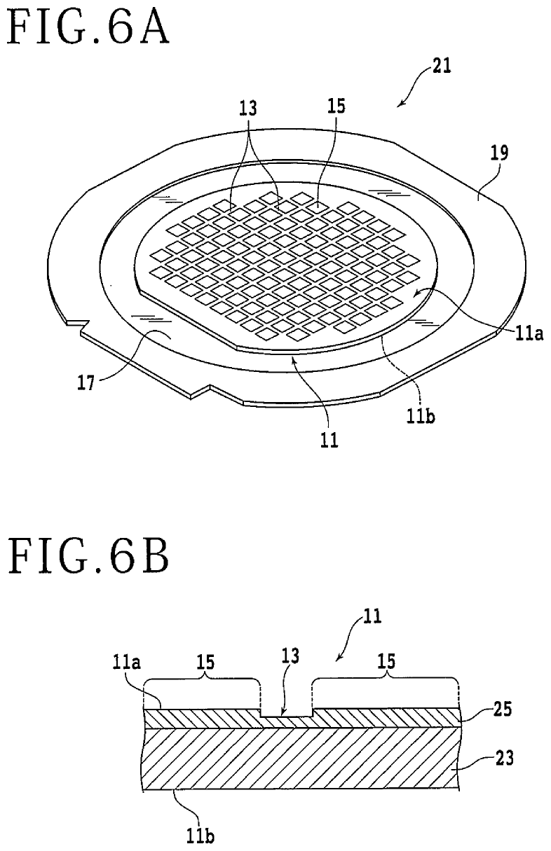

Now, a method of cutting a wafer 11 using the cutting blade 2 is described. First, a configuration of the wafer 11 is described with reference to FIGS. 6A and 6B. The wafer 11 has a disk-shaped substrate 23 formed principally from silicon. However, there is no restriction to the material of the substrate 23. The substrate 23 may be formed of gallium arsenide (GaAs), gallium nitride (GaN), silicon carbide (SiC) or the like. On one face side of the substrate 23 (namely, on the front face 11a side of the wafer 11), a multilayer wiring layer 25 is provided. The multilayer wiring layer 25 is a stacked body in which an insulating film (not depicted) formed of a low dielectric insulator material (what is generally called a Low-k material) and a metal layer (not depicted) are stacked alternately. In short, in the multilayer wiring layer 25, insulating films (namely, Low-k films) formed of a Low-k material and so forth are stacked.

On the front face 11a side of the wafer 11, pluralities of scheduled division lines 13 are set in a grating pattern. In each of a plurality of regions partitioned by the pluralities of scheduled division lines 13, a device 15 is formed. Each device 15 is formed of a function region formed to a predetermined depth in the inside of the substrate 23 from the one face of the substrate 23 and a wiring region positioned on the function region of the multilayer wiring layer 25. This wiring region is a projected portion that protrudes upwardly farther than the region of the multilayer wiring layer 25 in which the scheduled division lines 13 are set.

Before the wafer 11 is cut, a circular dicing tape 17 having a diameter greater than the wafer 11 is stuck on the rear face 11b side (namely, on the other face side of the substrate 23) of the wafer 11 positioned on the opposite side to the front face 11a. Further, a ring-shaped frame 19 made of metal is stuck at one face side thereof on an outer peripheral portion of the dicing tape 17. A wafer unit 21 in which the wafer 11 is supported on the frame 19 through the dicing tape 17 is formed in this manner. FIG. 6A is a perspective view of the wafer unit 21, and FIG. 6B is a sectional view of the wafer 11 and so forth.

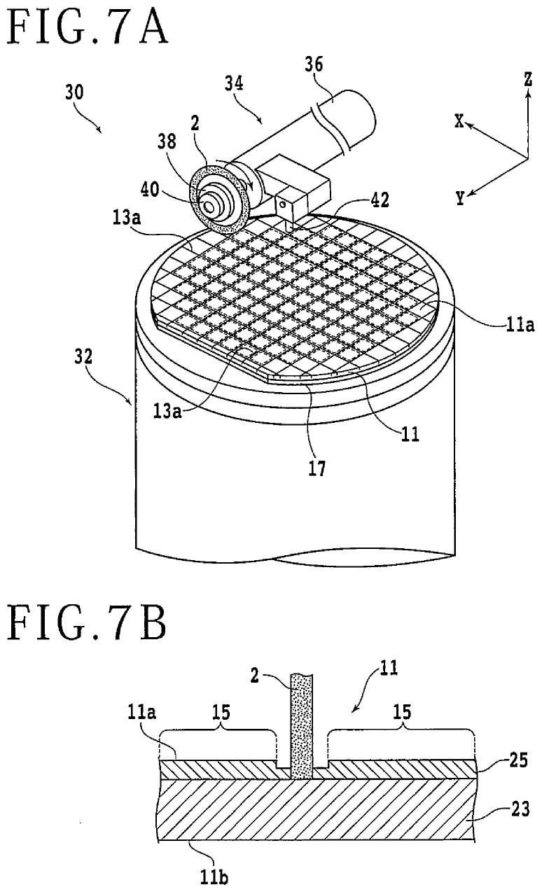

The wafer 11 is cut, for example, using a cutting apparatus 30. Therefore, the cutting apparatus 30 is described with reference to FIG. 7A. The cutting apparatus 30 includes a chuck table 32 that sucks and holds the rear face 11b side of the wafer 11 thereon. The chuck table 32 has a porous plate (not depicted) of a substantially disk shape. On the rear face (lower face) side of the porous plate, a flow path (not depicted) is connected, and this flow path is connected to a suction source such as an ejector. If the suction source is rendered operative, then negative pressure is generated on the front face (upper face) side of the porous plate.

Below the chuck table 32, a 0 table (not depicted) for rotating the chuck table 32 is connected. Below the 0 table, an X-axis direction moving unit (not depicted) is provided. The X-axis direction moving unit moves the 0 table, the chuck table 32 and so forth along an X-axis direction. Above the chuck table 32, a cutting unit 34 is provided. The cutting unit 34 has a spindle housing 36, and a cylindrical spindle (not depicted) is accommodated for rotation in the spindle housing 36. Further, at a distal end portion of the spindle, a threaded hole (not depicted) to which a fixing member such as a bolt is fastened is formed.

At a distal end portion of the spindle, a rear flange (not depicted) of a substantially disk shape is arranged. At the center of the rear flange, a predetermined hole (not depicted) substantially equivalent to the threaded hole of the spindle is formed. If a bolt is fastened to the threaded hole in a state in which the hole of the rear flange and the threaded hole of the spindle are aligned with each other, then a ring-shaped portion around the hole of the rear flange is sandwiched between and fixed by the head of the bolt and the distal end portion of the spindle. On the rear flange, a cylindrical boss portion (not depicted) is formed on the opposite side to the side on which the rear flange contacts with the spindle. An outer diameter of the boss portion is smaller than the through-hole 4 of the cutting blade 2 described above, and a male thread is formed on an outer peripheral portion of a distal end portion of the boss portion. The position of the cutting blade 2 is fixed by sandwiching the same between the rear flange described above and a ring-shaped front flange 38.

In particular, the through-hole 4 of the cutting blade 2 is first fitted with the boss portion, and then the through-hole (not depicted) of the front flange 38 is fitted with the boss portion. Then, a ring-shaped holding nut 40 having a thread formed on the inner circumference side thereof is fastened to the male thread of the boss portion. Consequently, the cutting blade 2 is sandwiched by and between the rear flange and the front flange 38. On a side portion of the spindle housing 36, a camera unit 42 for imaging an imaging object such as the wafer 11 arranged on the lower side is provided. The camera unit 42 is used for detection (alignment) of a scheduled division line 13, check of the kerf width and so forth.

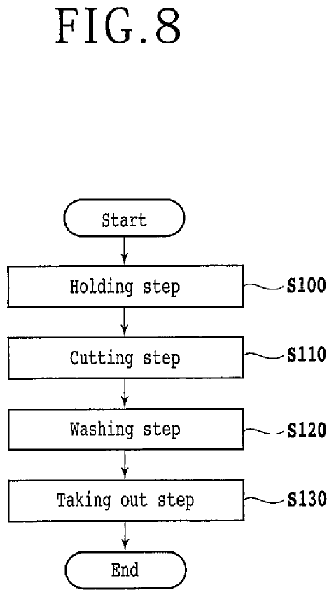

Now, a cutting method of the wafer 11 using the cutting apparatus 30 is described. FIG. 8 is a flow chart illustrating the cutting method. First, the wafer unit 21 is placed on the chuck table 32 and the suction source is rendered operative. The wafer 11 is sucked and held on the rear face 11b side thereof by the chuck table 32 in a state in which the multilayer wiring layer 25 is exposed (holding step (S100)). After the holding step (S100), the camera unit 42 is used to detect a scheduled division line 13 of the wafer 11.

Then, the chuck table 32 is rotated until one of the scheduled division lines 13 becomes substantially parallel to the X axis direction, and the cutting blade 2 is positioned at one of the scheduled division lines 13. Together with this, a lower end of the cutting blade 2 that rotates around an axis of rotation given by the spindle is positioned at a height of the boundary between the substrate 23 and the multilayer wiring layer 25 (namely, on one face of the substrate 23). Then, the X-axis direction moving unit is used to relatively move the cutting blade 2 and the chuck table 32 along the X axis direction. Consequently, the multilayer wiring layer 25 is cut along the one scheduled division line 13 and the insulating film of the multilayer wiring layer 25 is cut by the cutting blade 2 (cutting step (S110)).

FIG. 7A is a perspective view of the wafer unit 21 and so forth in the cutting step (S110), and FIG. 7B is a sectional view of the wafer 11 in the cutting step (S110). As described hereinabove, the cutting blade 2 is formed, at least at part of the binder 2b, using glassy carbon. In this case, since the binder 2b becomes brittle in comparison with an electroformed bond blade or a metal bond blade, and the self-sharpening effect is likely to occur in the cutting blade 2. Accordingly, in comparison with an alternative case in which an electroformed bond blade or a metal bond blade is used for cutting, the cutting blade 2 becomes less likely to give a shock to an insulating film that is likely to exfoliate. Therefore, since the insulating film becomes less likely to suffer from a break or a crack, exfoliation of the insulating film that is likely to exfoliate upon cutting can be suppressed.

Further, since the average particle size of the abrasive particles 2a is smaller than the blade thickness of the outer circumferential portion of the cutting blade 2 (for example, in the case where the outer circumferential portion of the cutting blade 2 has a blade thickness of 20 μm to 30 μm, the average particle size of the abrasive particles 2a is equal to or smaller than 12 μm), it is possible to reduce the influence of the abrasive particles 2a upon a workpiece and suppress exfoliation of an insulating film that is likely to exfoliate upon cutting. The multilayer wiring layer 25 is cut to form a cut groove 13a exposed along the scheduled division line 13. After the cut groove 13a is formed along every scheduled division line 13, the bottom of the cut groove 13a is cut using another cutting blade (cutting step (S110)). By cutting the wafer 11 along all scheduled division lines 13 in this manner, a plurality of chips (not depicted) are manufactured.

After the plurality of chips are manufactured, the wafer 11 is transported to a washing unit (not depicted), by which the wafer 11 is washed (washing step (S120)). After the washing step (S120), the plurality of chips are individually taken out from the dicing tape 17 (taking out step (S130)). It is to be noted that, while, in the example described above, the substrate 23 is severed by another cutting blade after the scheduled division lines 13 are formed in the multilayer wiring layer 25 by the cutting blade 2, only the cutting blade 2 may be used to sever both the multilayer wiring layer 25 and the substrate 23. Further, the structures, methods and so forth according to the embodiment described above can be carried out in a suitably altered form without departing from the scope of the object of the present invention. For example, the target to be cut by the cutting blade 2 is not limited to the Low-k film of the multilayer wiring layer 25. A passivation film (insulating film) that is likely to exfoliate upon cutting may be cut using the cutting blade 2. Also in this case, the insulating film can be cut while exfoliation of the insulating film that is likely to exfoliate upon cutting is suppressed.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A cutting blade having a binder and abrasive particles, wherein
the abrasive particles are fixed by the binder at least part of which is glassy carbon.

2. The cutting blade according to claim 1, wherein
the abrasive particles of the cutting blade have an average particle size equal to or smaller than 12 μm.

3. A manufacturing method of a cutting blade in which abrasive particles are fixed by a binder, comprising:
a molding step of forming a molded body of a predetermined shape from mixture including a thermosetting resin and the abrasive particles;
a baking step of baking the molded body at a temperature equal to or higher than 100° C. and equal to or lower than 300° C. to form a baked body; and
a heat treatment step of heat treating the baked body at a temperature equal to or higher than 500° C. and equal to or lower than 1500° C. under an inert gas atmosphere or a vacuum atmosphere, wherein,
in the heat treatment step, at least part of the thermosetting resin is the binder of glassy carbon.

4. A cutting method of a wafer for cutting an insulating film provided on a front face side of the wafer on which a device is formed in each of a plurality of regions partitioned by scheduled division lines set in a grating pattern, the cutting method comprising:
a holding step of sucking and holding a rear face side positioned on an opposite side to the front face of the wafer by a chuck table to hold the wafer in a state in which the front face side is exposed; and
a cutting step of cutting the insulating film positioned on the front face side along the scheduled division lines using a cutting blade in which abrasive particles are fixed by a binder at least part of which is glassy carbon.

5. The cutting method according to claim 4, wherein,
in the cutting step, the insulating film is cut using the cutting blade in which the abrasive particles have an average particle size equal to or smaller than 12 μm.
